(19) United States
(12) Patent Application Publication
(10) Pub. No.: US 2009/0314607 A1
(43) Pub. Date: Dec. 24, 2009

(54) ELECTRONIC DEVICE CONVEYING METHOD AND ELECTRONIC DEVICE HANDLING APPARATUS

(75) Inventors: Koya Karino, Tokyo (JP); Akihiko Ito, Tokyo (JP)

Correspondence Address: POSZ LAW GROUP, PLC, 12040 SOUTH LAKES DRIVE, SUITE 101, RESTON, VA, 20191, US

(73) Assignee: Advantest Corporation, Tokyo (JP)

(21) Appl. No.: 12/309,678

(22) PCT Filed: Jul. 27, 2006
(86) PCT No.: PCT/JP2006/314850

§ 371 Date: Apr. 14, 2009

(51) Int. Cl. B65G 43/00; G01R 19/00

(52) U.S. Cl. 198/341.01; 324/76.11

(57) ABSTRACT

In a handler comprising a movable head (suction pads) capable of holding and conveying a plurality of pre-test IC devices at a time: when conveying a plurality of pre-test IC devices from a supply customer tray KST to a test tray TST, a first step of leaving on the customer tray KST pre-test IC devices loaded on positions corresponding to turned-off sockets, holding by the suction pads only pre-test IC devices on the customer tray KST loaded on positions corresponding to other sockets than the turned-off ones and conveying them from the customer tray KST to the test tray TST without changing the arrangement; and a second step of conveying pre-test IC devices left on the customer tray KST for the reason of being at positions corresponding to the turned-off sockets from the customer tray KST to positions on the test tray TST corresponding to other sockets than the turned-off sockets are performed.

### TECHNICAL FIELD

The present invention relates to an electronic device handling apparatus for conveying a plurality of electronic devices to conduct tests on the electronic devices, such as IC devices, and to a method for conveying a plurality of electronic devices in the electronic device handling apparatus.

### BACKGROUND ART

In a production procedure of an electronic device, such as an IC device, a testing apparatus for testing a finally produced electronic device becomes necessary. In such a testing apparatus, an electronic device handling apparatus called a handler conveys a large amount of IC devices by storing them on a test tray, brings external terminals of the respective IC devices electrically contact with connection terminals of sockets provided on a test head to conduct a test by a main testing device (tester). In this way, IC devices are tested and classified to categories of at least good ones and defective ones.

Pre-test IC devices are normally stored on a customer tray for supplying (supply tray) and conveyed to a test tray by being picked up from the supply tray by a plurality of (for example, four) suction pads provided to a movable head of an X-Y conveyor device in the above electronic device handling apparatus.

Here, among the plurality of sockets on the test head, some sockets may be set to be unusable (turned-off sockets) due to defects, etc. of the connection terminals. Because sockets being set to be turned-off cannot conduct any test, IC devices should not be conveyed to those turned-off sockets, consequently, should not be conveyed to IC device storing portions at corresponding positions thereto on the test tray.

Therefore, conventionally, a plurality of (for example, four) IC devices held by suction pads are successively stored only in IC device storing portions at positions on the test tray corresponding to sockets which are not set to be turned-off while avoiding IC device storing portions at positions on the test tray corresponding to turned-off sockets.

Accordingly, IC devices picked up by the suction pads cannot be stored in the IC device holding portions on the test tray at one time but they are stored separately over a plurality of times. Namely, a so-called touchdown is repeated for a plurality of times for the IC devices picked up by the suction heads to be stored in IC device storing portions corresponding to other sockets than the turned-off sockets. Therefore, there arise disadvantages that the conveyance efficiency becomes poor, throughput declines and test efficiency deteriorates.

Furthermore, after a test on IC devices finishes, while being classified in accordance with the test results, the IC devices stored in the IC device storing portions on the test tray are conveyed to customer trays for classification (classification trays) by suction pads of a movable head of an X-Y conveyor device. At this time, there may be IC devices having different test results on one test tray. Accordingly, in some cases, a plurality of (for example, four) IC devices held by the suction pads may include ones having different test results.

In that case, conventionally, among IC devices held by the suction pads, those having the one test result (for example, IC devices determined as good ones) are successively stored on a classification tray (for good ones) without leaving any space between them and those having other test results (for example, IC devices determined to be defective ones) are successively stored on a classification tray (for defective ones) without leaving any space between them.

In the above case, for example, when a plurality of IC devices picked up by the suction pads are arranged in an order of one determined to be good, one determined to be good, one determined to be defective and one determined to be good; two IC devices determined to be good are stored in the IC device storing portions of the classification tray for good ones first, then, the movable head is moved to store the remaining good IC device on an IC device storing portion right next to the two good IC devices. Then, the movable head is moved again to store the defective IC device on an IC device storing portion of the classification tray for defective ones.

As explained above, when a plurality of IC devices picked up by the suction pads include ones having different test results, IC devices having the one test result cannot be stored in IC device storing portions of a classification tray in one time but they need a plurality of times to be stored in some cases. In this case also, a touchdown has to be repeated for several times and there are disadvantages that the conveyance efficiency becomes poor, throughput declines and test efficiency deteriorates.

### DISCLOSURE OF THE INVENTION

### Problem to be Solved by the Invention

The present invention was made in consideration of the above circumstances and has as an object thereof to provide an electronic device conveying method and an electronic device handling apparatus capable of improving the conveyance efficiency by decreasing the number of times of touchdowns by an electronic device holder at the time of conveying electronic devices.

### Means for Solving the Problem

To attain the above object, firstly, the present invention provides an electronic device conveying method for conveying a plurality of pre-test electronic devices from the first area where pre-test electronic devices are loaded to the second area where pre-test electronic devices are to be loaded or tested, in an electronic device handling apparatus comprising a holder capable of holding and conveying a plurality of pre-test electronic devices at a time:

wherein the respective positions in the second area are set to be available for conveyance when pre-test electronic devices may be conveyed to or to be unavailable for conveyance when no pre-test electronic devices should be conveyed thereto in accordance with predetermined conditions;

comprising
a first step of leaving pre-test electronic devices loaded on positions in the first area corresponding to positions in the second area set to be unavailable for conveyance, holding by the holder only pre-test electronic devices loaded on positions in the first area corresponding to positions in the second area set to be available for conveyance and, without changing an arrangement of the pre-test electronic devices being held, conveying directly or indirectly from the first area to the second area set to be available for conveyance; and
a second step of conveying from the first area to the second area set to be available for conveyance the pre-test electronic devices left at the first area because they are loaded on positions at the first area corresponding to the second area set to be unavailable for conveyance (Invention 1).

According to the above invention (Invention 1), by leaving pre-test electronic devices loaded on positions in the first area corresponding to positions in the second area set to be unavailable for conveyance, holding by the holder only pre-test electronic devices loaded on positions in the first area corresponding to positions in the second area set to be available for conveyance, and conveying them from the first area to the second area without changing an arrangement of the pre-test electronic devices at the state of being held; the number of times of touchdowns to the second area can become one in one conveyance. Also, pre-test electronic devices left at the first area for the reason of being loaded on positions in the first area corresponding to positions in the second area set to be unavailable for conveyance can be conveyed in a lot in another step, the number of times of touchdowns can be reduced as a whole and, thereby, the conveyance efficiency can be improved.

In the above invention (Invention 1), it is preferable that the first step is performed repeatedly until all of pre-test electronic devices loaded on positions in the first area corresponding to the second area set to be available for conveyance among pre-test electronic devices loaded at the first area are conveyed to the second area and, then, the second step is performed (Invention 2).

According to the above invention (Invention 2), after conveying all of pre-test electronic devices loaded on positions in the first area corresponding to positions in the second area set to be available for conveyance, pre-test electronic devices left on the first area are conveyed; so that the pre-test electronic devices left at the first area can be conveyed effectively in a lot. Accordingly, the number of times of touchdowns can be effectively reduced as a whole and, thereby, the conveyance efficiency can be improved.

In the above invention (Invention 1), the first area may be electronic device storing portions of a supply tray (Invention 3), and the second area may be electronic device storing portions of a test tray (Invention 4). Note that the present invention is not limited to that and, for example, the first area and the second area may be a transfer board (which circulates inside the electronic device handling apparatus in the same way as the test tray, but it only transfers and not used in a test), other transfer medium (for example, a transfer board), a heat plate portion of a logic handler or a part for temporarily collecting electronic devices when conveying electronic devices (it is provided, for example, when the number of buffer portions and precisers is large) and, particularly, the second area may be a socket.

Secondary, the present invention provides an electronic device conveying method for conveying a plurality of post-test electronic devices while classifying them based on test results from the first area where post-test electronic devices are loaded to the second area where post-test electronic devices are to be loaded in an electronic device handling apparatus comprising a holder capable of holding and conveying a plurality of post-test electronic devices at a time:

comprising a first step of holding by the holder post-test electronic devices having predetermined or arbitrary test results among post-test electronic devices loaded on the first area and conveying them directly or indirectly from the first area to the second area, and loading post-test electronic devices having the one test result among the post-test electronic devices having predetermined or arbitrary test results on the second area in an arrangement corresponding to an arrangement of being held by the holder (Invention 5).

According to the above invention (Invention 5), by loading post-test electronic devices having the one test result on the second area in an arrangement corresponding to an arrangement in a state of being held by the holder, the number of times of touchdowns to the second area can become one in one conveyance and, thereby, the conveyance efficiency can be improved.

In the above invention (Invention 5), the post-test electronic devices having predetermined or arbitrary test results may only include the post-test electronic devices having the one test result (Invention 6), or the post-test electronic devices having predetermined or arbitrary test results may include the post-test electronic devices having the one test result and post-test electronic devices having other test results (Invention 7). Also, the predetermined or arbitrary test results may include all kinds of test results, and post-test electronic devices may be held regardless of the test results when holding the post-test electronic devices loaded on the first area by the holder (Invention 8).

According to the above invention (Invention 6), since only post-test electronic devices having the one test result are held and conveyed from the first area, it is possible to unfailingly prevent post-test electronic devices having other test results from being mixed in at the second area on which post-test electronic devices having the one result are loaded.

Also, according to the above inventions (Inventions 7 and 8), a plurality of post-test electronic devices having different test results can be held and conveyed by the same holder, so that the number of times that the holder moves between the first area and the second area can be decreased and, thereby, the conveyance efficiency can be improved.

In the above invention (Invention 5), the first area may be electronic device storing portions on a test tray, and the second area may be electronic device storing portions on a classification tray (Invention 9). Note that the present invention is not limited to that and, for example, the first area and the second area may be a transfer board (which circulates inside the electronic device handling apparatus in the same way as the test tray, but it only transfers and not used in a test), other transfer medium (for example, a transfer board), a heat plate portion of a logic handler or a part for temporarily collecting electronic devices when conveying electronic devices (it is provided, for example, when the number of buffer portions and precisers is large) and, particularly, the first area may be a socket.

In the above invention (Invention 5), it is preferable to furthermore comprise a second step of conveying and loading post-test electronic devices having the one test result onto the second area in an empty state on which post-test electronic devices have not been loaded in the first step (Invention 10).

According to the above invention (Invention 10), post-test electronic devices having the one test result can be loaded on the second area without leaving any space, so that the second area (for example, a classification tray) can be used effectively. As a result that post-test electronic devices having the one test result are conveyed in a lot in this second step, the number of times of touchdowns can be reduced as a whole in combination with the first step when conveying post-test electronic devices having the one test result, accordingly, the conveyance efficiency can be improved.

In the above invention (Invention 10), it is preferable that the first step is repeatedly performed until the first step can be no longer performed and, then, the second step is performed (Invention 11).

According to the above invention (Invention 11), when post-test electronic devices having the one test result loaded on the first area are those having the same test result, the number of times of conveyance in the first step can be increased to the maximum and the number of times of conveyance in the second step can be reduced to the minimum. Since the number of times of touchdowns is one in the first step, the number of times of touchdowns can be reduced to the minimum as a whole and, thereby, the conveyance efficiency can be improved most effectively.

In the invention above (Invention 11), the second area may be electronic device storing portions on a classification tray; and the first step may be repeatedly performed until the first step can be no longer performed for one classification tray (Invention 12), alternately, the first step may be repeatedly performed until the first step can be no longer performed for predetermined number of classification trays (Invention 13), or the first step may be repeatedly performed until the first step can be no longer performed under a condition of allowing the classification trays to be exchanged (Invention 14).

In the above invention (Invention 5), a third step of conveying post-test electronic devices having the one test result to the second area and loading on the second area without leaving any spaces between them may be furthermore provided (Invention 15).

According to the above invention (Invention 15), by performing the third step, it is possible to prevent generation of second area (for example, a classification tray) having empty portions to which post-test electronic devices are not conveyed, therefore, the second area can be used efficiently.

In the above invention (Invention 15), it is preferable that the third step is performed by using information on a supply tray storing pre-test electronic devices relating to one test lot as a trigger (Invention 16).

Information on the supply tray to be the trigger may be, for example, information that the last or a predetermined supply tray in one test lot is set to the loader section of the electronic device handling apparatus or information that loading of pre-test electronic devices from the last or a predetermined supply tray is completed, etc. The last or predetermined supply tray can be recognized by the number of supply trays stored in the electronic device handling apparatus or by using a sensor, etc. provided to the electronic device handling apparatus.

In the above invention (Invention 16), for example, when information on the final supply tray is used as the trigger, it is detected that the test will be finished soon, therefore, it is possible to prevent making a second area (for example, a classification tray) with empty spaces to which post-test electronic devices are not conveyed at the end, consequently, it is possible to prevent the second area from being used wastefully much. In the same way, when information on a predetermined supply tray is used as the trigger, it is possible to prevent, at a predetermined stage, generation of a second area having empty spaces to which post-test electronic devices are not conveyed.

In the above invention (Invention 5), a fourth step of reloading post-test electronic devices already loaded on the second area to the second area in an empty state on which post-test electronic devices have not been loaded in the first step may be furthermore provided (Invention 17).

According to the above invention (Invention 17), by reloading post-test electronic devices already loaded on the second area to a second area being empty on which post-test electronic devices have not been loaded, the post-test electronic devices can be loaded without leaving any space on the second area. Therefore, the second area (for example, a classification tray) can be used efficiently.

In the above invention (Invention 17), it is preferable that the fourth step is performed after all post-test electronic devices having the one test result among post-test electronic devices relating to one test lot are loaded on the second area (Invention 18).

According to the above invention (Invention 18), it is possible to prevent generation of empty spaces with no post-test electronic devices stored therein on the final second area (for example, a classification tray).

Thirdly, the present invention provides an electronic device handling apparatus capable of performing any one of the electronic device conveying methods in the above inventions (Inventions 1 to 18) (Invention 19). According to the electronic device handling apparatus according to the invention (Invention 19), electronic devices can be tested efficiently.

### ADVANTAGEOUS EFFECT OF THE INVENTION

According to the present invention, it is possible to decrease the number of times of touchdowns of a holder for holding electronic devices to be tested at the time of conveying the electronic devices and the conveyance efficiency can be improved.

### BRIEF DESCRIPTION OF DRAWINGS

FIG. 1 is an overall view from the side of an IC device testing apparatus including a handler according to an embodiment of the present invention.

FIG. 2 is a perspective view of the handler shown in FIG. 1.

FIG. 3 is a flowchart diagram of trays illustrating a method of handling IC devices to be tested.

FIG. 4 is a perspective view showing the configuration of an IC stocker of the above handler.

FIG. 5 is a perspective view showing a customer tray used in the above handler.

FIG. 6 is a sectional view of a key part inside a test chamber of the above handler.

FIG. 7 is a partially disassembled perspective view showing a test tray used in the above handler.

FIG. 8 is a flowchart diagram illustrating a conveying method of pre-test IC devices from a customer tray for supplying to a test tray in the above handler.

FIG. 9 is a flowchart diagram illustrating an example of a conveying method of post-test IC devices from a test tray to customer trays for classification in the above handler.

FIG. 10 is a flowchart diagram illustrating another example of a conveying method of post-test IC devices from a test tray to customer trays for classification in the above handler.

FIGS. 11(A) and (B) are views showing an example of a conveying method of post-test IC devices on a customer tray for classification in the above handler.

### EXPLANATION OF REFERENCES

1 . . . handler (electronic device handling apparatus)
2 . . . IC device (electronic device)
10 . . . IC, device (electronic device) testing apparatus
304, 404 . . . X-Y conveyor device
303, 403 . . . movable head
307, 407 . . . suction pad (holder)

### BEST MODE FOR CARRYING OUT THE INVENTION

Below, an embodiment of the present invention will be explained based on the drawings.

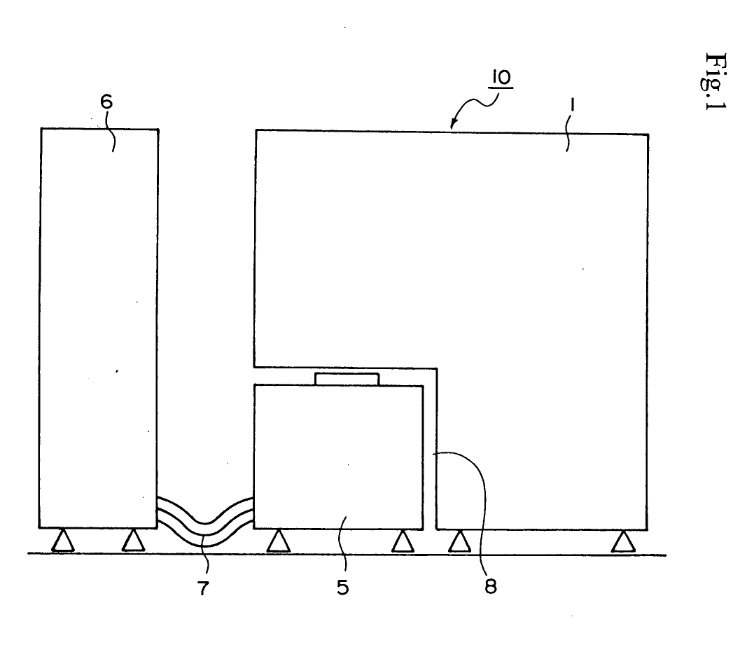

First, an overall configuration of an IC device testing apparatus provided with an electronic device handling apparatus (hereinafter, referred to as “a handler”) according to the present embodiment will be explained. As shown in FIG. 1, an IC device testing apparatus 10 comprises a handler 1, a test head 5 and a main testing device 6. The handler 1 performs an operation of successively conveying IC devices (an example of electronic devices) to be tested to sockets provided on the test head 5, classifying IC devices finished with the test in accordance with the test results and storing on predetermined trays.

The sockets provided on the test head 5 are electrically connected to the main testing device 6 through a cable 7, IC devices attached detachably to the sockets are connected to the main testing device 6 through the cable 7 and tested by using a test electric signal from the main testing device 6.

In the lower portion of the handler 1, a control device for mainly controlling the handler 1 is incorporated and a space 8 is provided to a part thereof. The test head 5 is placed in a freely replaceable way in the space 8, and IC devices can be attached to the sockets on the test head 5 through a through hole formed on the handler 1.

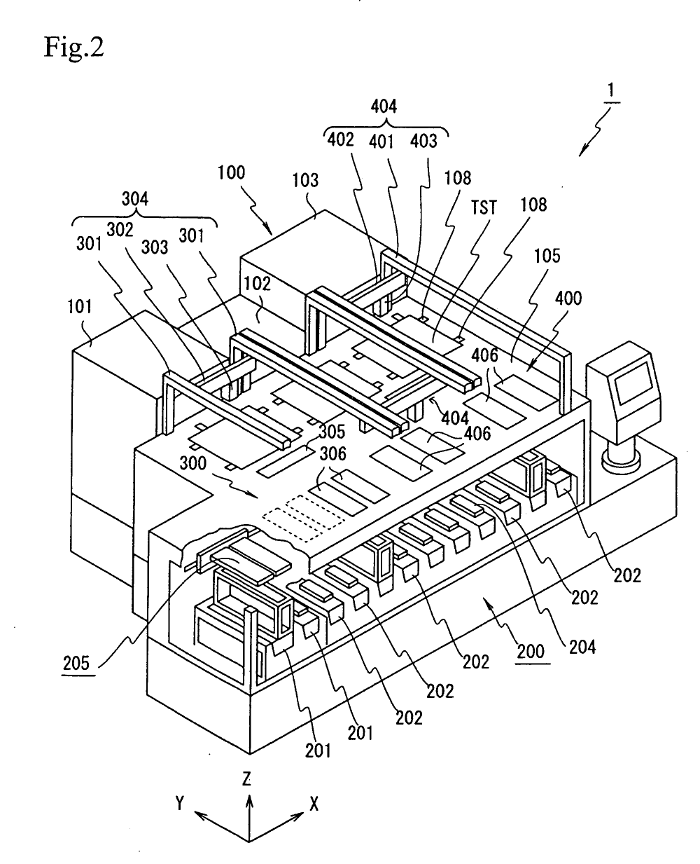

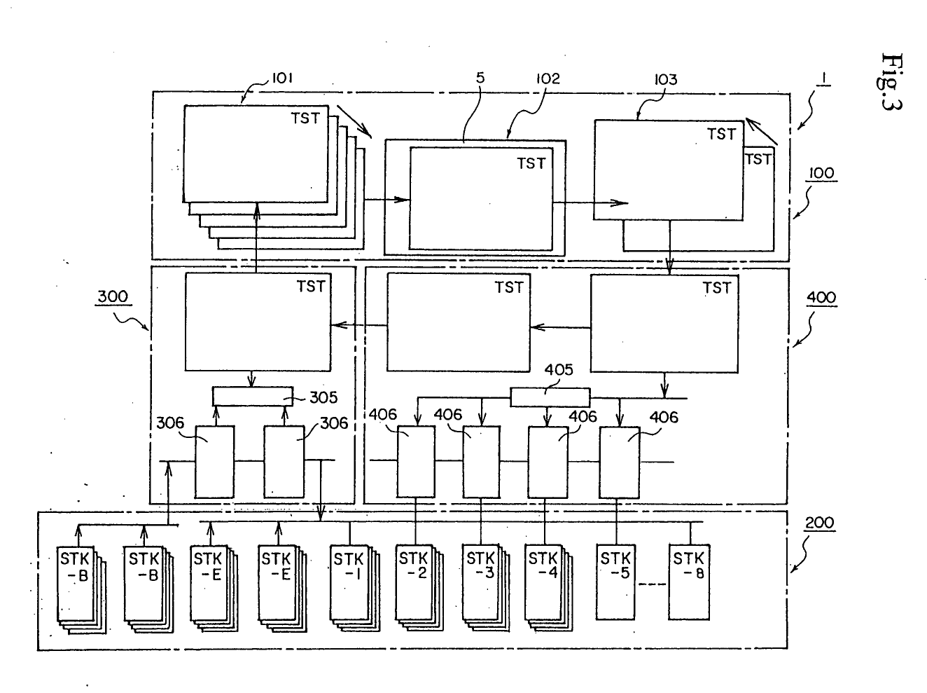

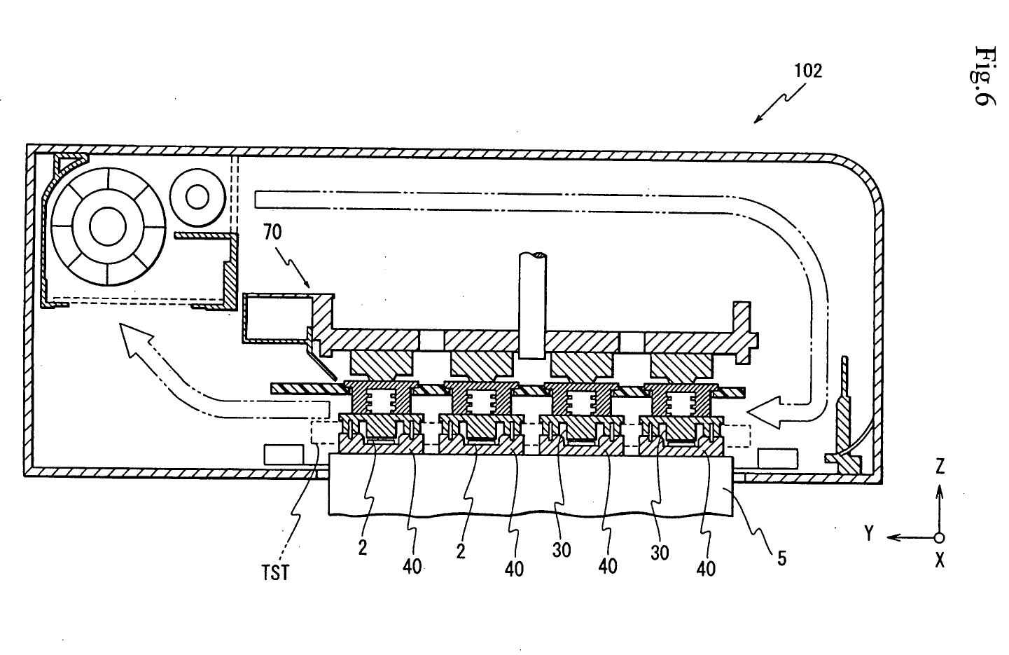

The handler 1 is an apparatus for conducting a test on IC devices as electronic devices to be tested in a higher temperature state (high temperature) or in a lower temperature state (low temperature) than the normal temperature. The handler 1 comprises, as shown in FIG. 2 and FIG. 3, a chamber 100 comprised of a constant temperature chamber 101, a test chamber 102 and an unsoak chamber 103. An upper portion of the test head 5 shown in FIG. 1 is inserted to inside of the test chamber 102 as shown in FIG. 6, where IC devices 2 are tested.

Note that FIG. 3 is a view for understanding a handling method of IC devices to be tested in the handler 1 of the present embodiment and partially shows by a plan view members actually arranged aligned in the vertical direction. Therefore, the mechanical (three-dimensional) structure can be understood mainly by referring to FIG. 2.

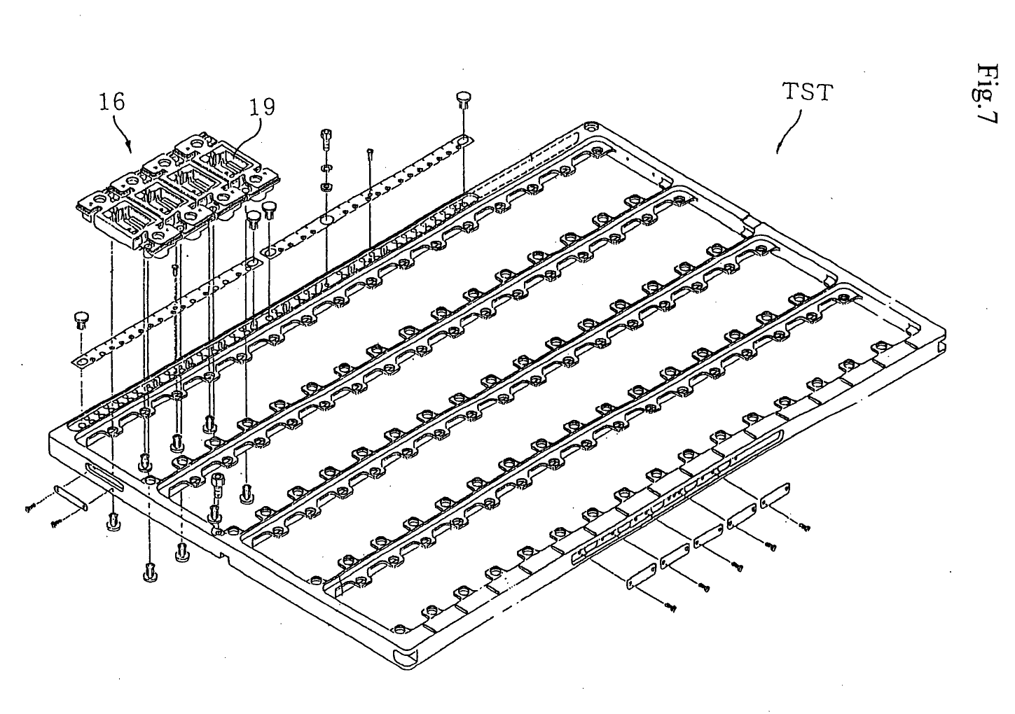

As shown in FIG. 2 and FIG. 3, the handler 1 of the present embodiment comprises an IC magazine 200 for storing IC devices to be tested and storing post-test IC devices by classifying them, a loader section 300 for transferring IC devices to be tested sent from the IC magazine 200 to the chamber 100, a chamber section 100 including the test head, and an unloader section 400 for taking out and classifying post-test IC devices finished with the test in the chamber section 100. Inside the handler 1, IC devices are stored on a test tray TST (refer to FIG. 7) while being conveyed.

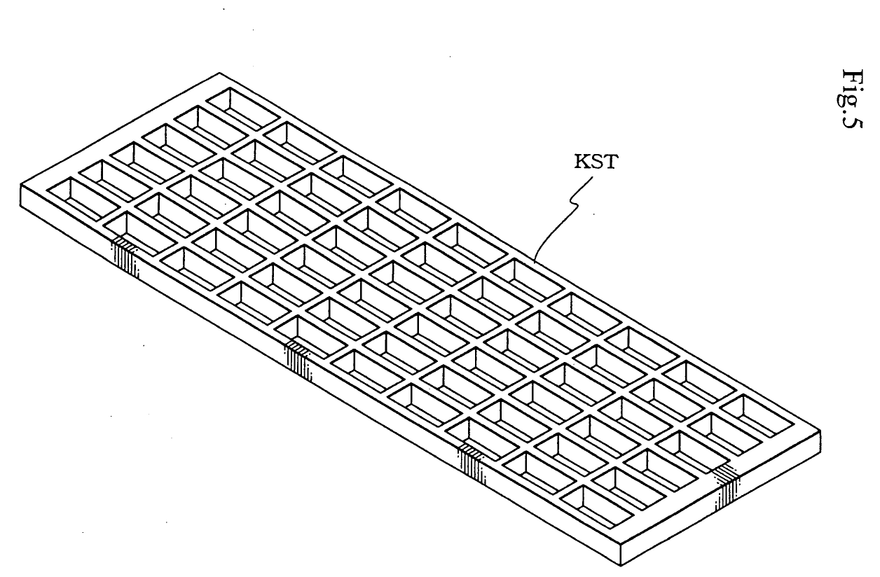

A large number of the IC devices are stored on the customer tray KST as shown in FIG. 5 before being set in the handler 1, supplied in that state to the IC magazine 200 of the handler 1 shown in FIG. 2 and FIG. 3, where the IC devices 2 are reloaded from the customer tray KST to the test tray TST, to be conveyed in the handler 1. Inside the handler 1, as shown in FIG. 3, the IC devices 2 are moved in a state of being loaded on the test tray TST, given a thermal stress of a high temperature or a low temperature for testing (inspecting) whether or not they operate appropriately and classified in accordance with the test results. Below, a detailed explanation will be made individually on inside the handler 1.

First, a part relating to the IC magazine 200 will be explained.

As shown in FIG. 2, the IC magazine 200 is provided with pre-test IC stockers 201 for storing IC devices before tested and post-test IC stockers 202 for storing IC devices classified in accordance with the test results.

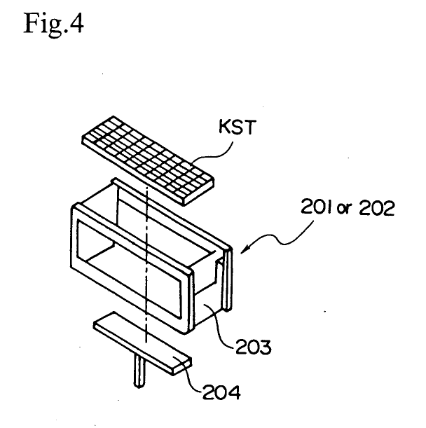

As shown in FIG. 4, each of the pre-test IC stockers 201 and post-test IC stockers 202 is provided with a frame-shaped tray support frame 203 and an elevator 204 for moving up and down by approaching from below the tray support frame 203 toward upward. The tray support frame 203 supports a plurality of stacked customer trays KST, and the stacked customer trays KST are moved up and down by the elevator 204.

Here, the customer tray KST shown in FIG. 5 has IC device storing portions by 10 lines×6 rows, but it is not limited to this and a customer tray KST having IC device storing portions by 5 lines×4 rows will be shown as an example in the later explanation.

The pre-test IC stocker 201 shown in FIG. 2 holds stacked customer trays KST on which the IC devices to be tested (pre-test IC devices) are stored. The post-test IC stocker 202 holds stacked customer trays KST on which IC devices classified after finishing with the test (post-test IC devices) are stored.

Note that the pre-test IC stockers 201 and the post-test IC stockers 202 have approximately the same configuration, so that some of the pre-test IC stockers 201 may be used as the post-test IC stockers 202 and the opposite is also possible. Accordingly, the number of the pre-test IC stockers 201 and that of the post-test IC stockers 202 may be easily changed if needed.

As shown in FIG. 2 and FIG. 3, in the present embodiment, two stockers STK-B are provided as the pre-test IC stockers 201. Next to the stockers STK-B, two empty stockers STK-E to be sent to the unloader section 400 are provided as the post-test IC stockers 202. Furthermore, next to that, eight stockers STK-1, STK-2, . . . , STK-8 are provided as the post-test IC stockers 202 and configured to be able to store IC devices classified into a maximum of eight classes according to the test results. That is, in addition to classifying to good and defective, it is possible to classify the good IC devices into ones with high operating speeds, ones with medium speeds, and ones with low speeds and the defective IC devices into ones requiring retesting, etc.

Secondary, parts related to the loader section 300 will be explained.

As shown in FIG. 2, on an apparatus substrate 105 of the loader section 300, a pair of windows 306 and 306 are formed by three pairs in an arrangement, by which the customer tray KST for supply faces to an upper face of the apparatus substrate 105. A tray set elevator (not shown) for elevating and lowering the customer tray KST is provided below each of the windows 306. Also, as shown in FIG. 2, tray transfer arms 205 capable of moving back and forth in the X-axis direction are provided between the IC magazine 200 and the apparatus substrate 105.

The elevator 204 of the pre-test IC stocker 201 shown in FIG. 4 elevates a customer tray KST stored in the tray support frame 203. The tray transfer arm 205 receives the customer tray KST from the elevated elevator 204 and moves in the X-axis direction to give the customer tray KST to a predetermined tray set elevator. The tray set elevator elevates the received customer tray KST to make it exposed to the window 306 of the loader section 300.

Then, in the loader section 300, IC devices to be tested stored on the customer tray KST are temporarily conveyed by an X-Y conveyor device 304 to precisers 305, where mutual positions of the IC devices are corrected. After that, the IC devices transferred to the precisers 305 are furthermore loaded to a test tray TST rested at the loader section 300 by again using the X-Y conveyor device 304.

The X-Y conveyor device 304 for loading IC devices to be tested from a customer tray KST to a test tray TST comprises, as shown in FIG. 2, two rails 301 laid over the apparatus substrate 105, a movable arm 302 capable of moving back and forth (this direction designated as the Y-direction) between the test tray TST and the customer tray KST by the two rails 301 and a movable head 303 supported by the movable arm 302 and capable of moving in the X-direction along the movable arm 302.

The movable head 303 of the X-Y conveyor 304 has a plurality of suction pads 307 attached facing downward. The suction pads 307 move while drawing air to pick up the IC devices to be tested from the customer tray KST and load the IC devices to be tested on the test tray TST. For example, the suction pads as above are provided by the number of four arranged in the X-axis direction on the movable head 303, so it is possible to load maximum of four IC devices to be tested in one time on the test tray TST.

Thirdly, parts relating to the chamber 100 will be explained.

The test tray TST explained above is loaded with IC devices to be tested in the loader section 300, then, sent to the chamber 100 where each of the IC devices is tested in the state of being loaded on the test tray TST.

As shown in FIG. 2 and FIG. 3, the chamber 100 comprises a constant temperature chamber 101 for giving a thermal stress of an objected high or low temperature to IC devices to be tested loaded on the test tray TST, a test chamber 102 wherein the IC devices to be tested in a state of being given a thermal stress in the constant temperature chamber 101 are attached to sockets on the test head, and an unsoak chamber 103 for removing the given thermal stress from the IC devices tested in the test chamber 102.

In the unsoak chamber 103, the IC devices are brought back to the room temperature by blowing air when a high temperature was applied in the constant temperature chamber 101, or brought back to a temperature of a degree of not causing dew condensation by heating by a hot air or a heater, etc. when a low temperature was applied in the constant temperature chamber 101. Then, the IC devices brought to a normal temperature are taken out to the unloader section 400.

The constant temperature chamber 101 is provided with a vertical conveyor as shown conceptually in FIG. 3, and a plurality of test trays TST are held by the vertical conveyor to wait until the test chamber 102 becomes available. The IC devices to be tested are applied a thermal stress of a high temperature or a low temperature mainly while waiting here.

As shown in FIG. 6, a test head 5 is arranged at a lower center portion in the test chamber 102 and the test tray TST is transferred to be on the test head 5, where all IC devices 2 stored on the test tray TST are brought to electrically contact with the test head 5 and tested. When the test finishes, the test tray TST is removed a thermal stress in the unsoak chamber 103 so that the temperature of the post-test IC devices 2 are brought back to be room temperature, then, taken out to the unloader section 400 shown in FIG. 2 and FIG. 3.

Also, as shown in FIG. 2, at upper portion of the constant temperature chamber 101 is formed inlet opening for taking in the test tray TST from the apparatus substrate 105, and at upper portion of the unsoak chamber 103 is formed outlet openings for taking out the test tray TST to the apparatus substrate 105. The apparatus substrate 105 is provided with test tray conveyors 108 for taking in and out the test trays TST to and from the openings. The conveyors 108 are configured, for example, by rotation rollers, etc. The test tray TST taken out from the unsoak chamber 103 is transferred to the unloader section 400 by the test tray conveyor 108 provided on the apparatus substrate 105.

As shown in FIG. 7, a plurality of inserts 16 are attached to the test tray TST. On each of the inserts 16, IC devices storing portion 19 for storing IC device 2 is formed. By storing IC device 2 in the IC device holding portion 19 of the insert 16, the IC devices 2 are loaded on the test tray TST.

The test tray TST shown in FIG. 7 has inserts 16 (IC device storing portions 19) by 4 lines×16 rows, but it is not limited to this and a test tray TST having IC device storing portions 19 by 4 lines×8 rows will be shown as an example in the later explanation.

As shown in FIG. 6, on the test head 5, a plurality of sockets 40 having probe pins as connection terminals are fixed via a socket board (not shown). The number of sockets 40 corresponds to the number of IC device storing portions 19 on the test tray TST. Namely, they are provided by 4 lines×16 rows in the present embodiment, but 4 lines×8 rows in the later explanation.

Here, when some sockets 40 among the plurality of sockets 40 becomes unable to conduct a test on IC devices 2, for example, due to deformations of the connection terminals or failures of electrical paths, etc., the sockets 40 are set to be turned-off sockets. Because such sockets being set to be turned-off cannot conduct any test, IC devices 2 should not be conveyed to those turned-off sockets 40, consequently, should not be conveyed to IC device storing portions 19 at corresponding positions thereto on the test tray TST.

As shown in FIG. 6, pushers 30 corresponding to the number of the sockets 40 are provided on the upper side of the test head 5. The pushers 30 are freely movable in the Z-axis direction with respect to the test head 5 by a Z-axis drive 70. By moving downward, the pushers 30 press IC devices 2 against the sockets 40 to bring external terminals of the IC devices 2 electrically connected to the probe pins of the sockets 40 for conducting a test.

Note that the test tray TST is conveyed from the vertical direction (X-axis) with respect to the paper surface in FIG. 6 to between the pushers 30 and the sockets 40. As a conveying means of test trays TST inside the chamber 100, conveyor rollers, etc. may be used. For conveying and moving a test tray TST, the pushers 30 are elevated along the Z-axis direction by the Z-axis drive 70 and a sufficient clearance is formed for the test tray TST to be inserted between the pushers 30 and the sockets 40.

Fourthly, parts relating to the unloader section 400 will be explained.

The unloader section 400 shown in FIG. 2 and FIG. 3 is also provided with X-Y conveyor devices 404 and 404 having the same configuration as that of the X-Y conveyor device 304 provided to the loader section 300, and the X-Y conveyor devices 404 and 404 reload post-test IC devices from the test tray TST conveyed to the unloader section 400 to the customer tray KST.

As shown in FIG. 2, on the apparatus substrate 105 in the unloader section 400, two pairs of windows 406 and 406 are formed in an arrangement, by which the customer tray KST conveyed to the unloader section 400 faces to the upper surface of the apparatus substrate 105. A tray set elevator (not shown) for elevating and lowering the customer tray KST is provided below each window 406.

The tray set elevator moves downward while being loaded with a classification customer tray KST (classification tray) storing classified post-test IC devices. The tray transfer arm 205 shown in FIG. 2 receives the classification tray from the lowered tray set elevator and moves in the X-axis direction to give the classification tray to an elevator 204 (refer to FIG. 4) of a predetermined post-test IC stocker 202. As a result, the classification tray is stored in the post-test IC stocker 202.

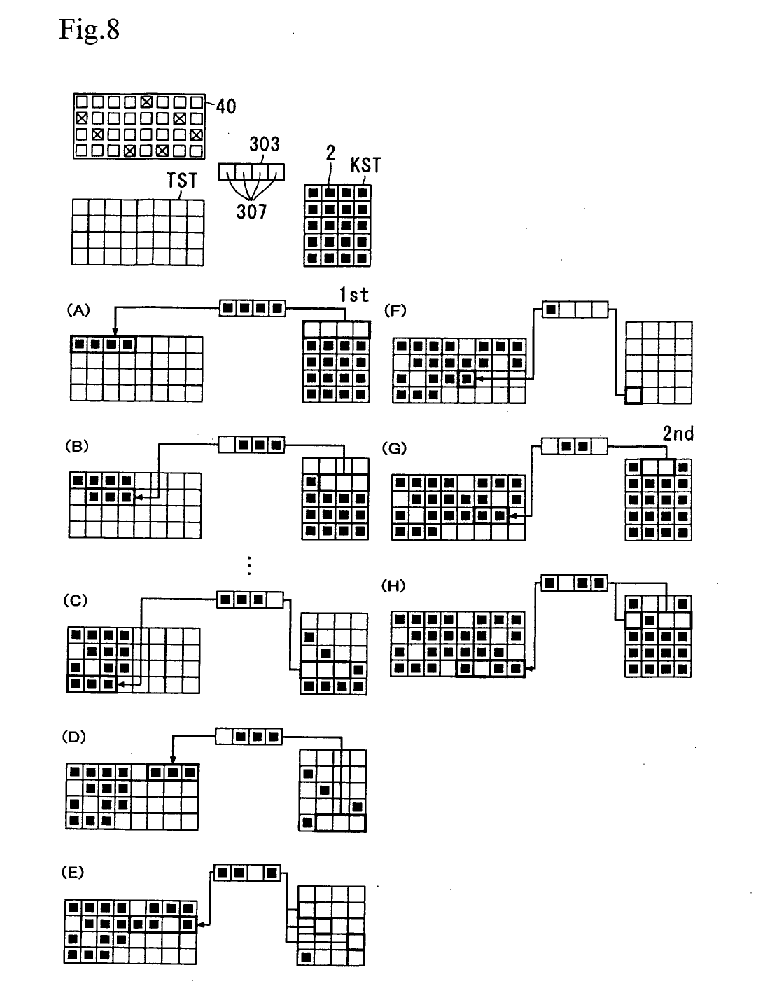

Here, a conveying method of pre-test IC devices 2 from a supply customer tray KST to a test tray TST in the above handler 1 will be explained with reference to FIG. 8. Note that, in FIG. 8, sockets 40 added with a mark “x” are those set to be turned-off. Also, to simplify the explanation, the stopover to the precisers 305 in the conveyance will be omitted.

First, as shown in FIG. 8(A), four suction pads 307 on the movable head 303 of the X-Y conveyor device 304 hold four pre-test IC devices 2 held on the first (the left end in FIG. 8) to fourth rows on the first line (the upper end in FIG. 8) on the customer tray KST at a time and, without changing the arrangement, store them in IC device storing portions 19 on the first (the left end in FIG. 8) to fourth rows on the first line (the upper end in FIG. 8) on the test tray TST. The number of times of touchdowns to the test tray TST is one at this time (hereinafter, same as above).

Next, on the first to fourth rows on the second line on the test tray TST, as shown in FIG. 8(B), since a socket 40 on the first row on the second line is set to be turned-off, the suction pads 307 do not hold an IC device 2 on the first row on the second line on the customer tray KST but hold three IC devices 2 stored on the second to fourth rows on the second line on the customer tray KST at a time and, without changing the arrangement, store the IC devices 2 in the IC device storing portions 19 on the second to fourth rows on the second line by skipping the IC device storing portion 19 on the first row on the second line on the test tray TST.

In the same way as explained above, IC devices 2 on the third to fifth lines on the customer tray KST are conveyed to the test tray TST (refer to FIGS. 8(C) and (D)). Namely, in order not to convey IC devices 2 to IC device storing portions 19 (on the second row on the third line, fourth row on the fourth line and first row on the fifth line) on the test tray TST corresponding to sockets 40 set to be turned-off, the suction pads 307 do not hold IC devices 2 (on second row on the third line, fourth row on the fourth line and first row on the fifth line) corresponding thereto on the customer tray KST but hold other IC devices 2 and store them in the IC device storing portions 19 on the test tray TST without changing the arrangement.

As explained above, when all of the IC devices 2 at positions corresponding to sockets 40 not being turned-off on the customer tray KST are conveyed to the test tray TST, then, remaining IC devices 2 (IC devices 2 remaining at positions corresponding to turned-off sockets 40) on the customer tray KST are conveyed to the test tray TST.

On the fifth to eighth rows on the second line on the test tray TST, as shown in FIG. 8(E), since sockets 40 on the seventh row on the second line is set to be turned-off, a suction pad 307 on the third row (the left end is the first row in FIG. 8) is left empty among the four suction pads 307 and IC devices 2 on the first row on the second line, second row on the third line and fourth row on the fourth line on the customer tray KST are held by the suction pads 307 on the first, second and fourth row. Then, without changing the arrangement, the IC devices 2 are stored in the IC device storing portions 19 on the fifth, sixth and eighth rows on the second line while leaving the IC device storing portion 19 on the seventh row on the second line empty on the test tray TST.

Next, as shown in FIG. 8(F), the first-row suction pad 307 holds the one IC device 2 remaining on the customer tray KST and stores it in the IC device storing portion 19 on the fifth row on the third line on the test tray TST.

As explained above, conveyance of IC devices 2 stored on the first customer tray KST to the test tray TST is completed, however, since there remains some IC device storing portions 19 capable of storing IC devices 2 on the test tray TST, IC devices 2 are conveyed from the second customer tray KST.

As shown in FIG. 8(G), on the fifth to eighth rows on the third line on the test tray TST, an IC device 2 is already stored in the IC device holding portion 19 on the fifth row on the third line, and a socket 40 on the eighth row on the third line is set to be turned-off. Therefore, the suction pads 307 do not hold IC devices 2 on the first and fourth rows on the first line on the customer tray KST but hold two IC devices 2 stored on the second and third rows on the first line at a time and, without changing the arrangement, store the IC devices 2 in the IC device storing portions 19 on the sixth and seventh rows on the third line on the test tray TST.

Finally, on the fifth to eighth rows on the fourth line on the test tray TST, as shown in FIG. 8(H), since a socket 40 on the sixth row on the fourth line is set to be turned-off, the suction pads 307 do not hold an IC device on the second row on the second line on the customer tray KST but hold three IC devices 2 stored on the first, third and fourth rows on the second line at a time and, without changing the arrangement, store the IC devices 2 in the IC device storing portions 19 on the fifth, seventh and eighth rows on the fourth line.

In this way, conveyance of pre-test IC devices 2 to one test tray TST completes. Conveyance of pre-test IC devices 2 to the second test tray TST and later can be performed in the same way as explained above by using the above second and later customer trays KST.

According to the conveying method of pre-test IC devices 2 explained above, pre-test IC devices 2 at positions corresponding to turn-off sockets 40 are not held but only pre-test IC devices 2 at positions corresponding to not turned-off sockets 40 are held and the pre-test IC devices 2 are conveyed to the test tray TST in the same arrangement, so that the number of times of touchdowns to the test tray TST can be one in one-time conveyance. Accordingly, comparing with conventional conveying methods, the number of times of touchdowns can be widely reduced, consequently, the conveyance efficiency can be improved, and the throughput and test efficiency can be improved.

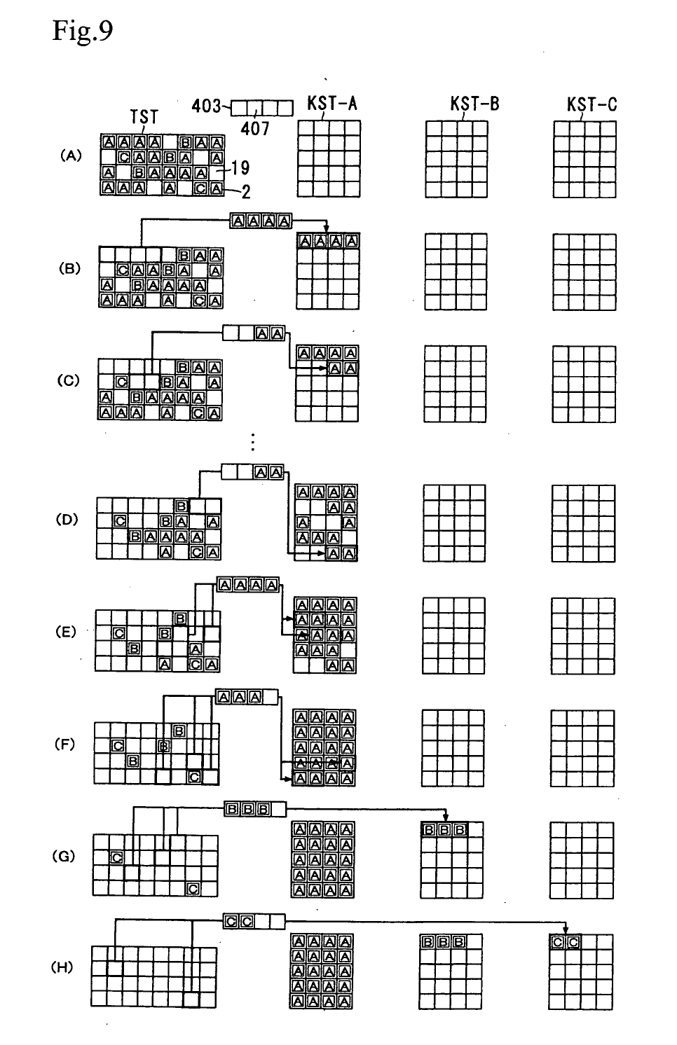

Next, with reference to FIG. 9, an example of a conveying method of post-test IC devices 2 from the test tray TST to classification customer trays KST in the above handler 1 will be explained.

As shown in FIG. 9(A), there are post-test IC devices 2 having different test results (for example, test results A, B and C) on one test tray TST. Parts with no IC devices 2 are IC device storing portions 19 to which no IC devices 2 were conveyed for the reason of being corresponding to turned-off sockets. In this example, first, only IC devices 2 having the test result A are conveyed to a classification customer tray KST.

First, on the first (the left end in FIG. 9) to fourth rows on the first line (the upper end in FIG. 9) on the test tray TST, as shown in FIG. 9(A), IC devices 2 each having a test result A are stored respectively in the IC device storing portions 19 on the first to fourth rows on the first line on the test tray, so that four suction pads 407 on the movable head 403 of the X-Y conveyor device 404 hold the IC devices 2 having test results A stored on the first to fourth rows on the first line on the test tray TST at a time as shown in FIG. 9(B). Then, without changing the arrangement, the IC devices 2 having test results A are stored in the IC device storing portions on the first (the left end in FIG. 9) to the fourth rows on the first line (the upper end in FIG. 9) on a customer tray KST-A for storing devices with test results A. At this time, the number of times of touchdowns to the customer tray KST-A is one.

Next, on the first to fourth rows on the second line on the test tray TST, as shown in FIG. 9(A), IC devices 2 having test results A are stored in the IC device storing portions 19 on the third and fourth rows on the second line on the test tray TST, so that the suction pads 407 on the third and fourth rows, as shown in FIG. 9(C), hold the IC devices 2 having test results A stored on the third and fourth rows on the second line on the test tray TST at a time (the suction pads 407 on the first and second rows are empty). Then, without changing the arrangement, the IC devices 2 with test results A are stored in the IC device storing portions on the third and fourth rows on the second line on the customer tray KST-A while leaving the IC device storing portions empty on the first and second rows on the second lines.

In the same way as explained above, IC devices 2 having test results A on the first to fourth rows on the third line, first to fourth rows on the fourth line and fifth to eighth rows on the first line on the test tray TST are conveyed to the customer tray KST-A (refer to FIG. 9(D)). Namely, the suction pads 407 convey IC devices 2 having test results A on the first row and fourth row on the third line on the test tray TST to the IC device storing portions on the first and fourth rows on the third line on the customer tray KST-A (leaving the second and third rows on the third line empty) in the same arrangement, convey IC devices 2 having test results A on the first to third rows on the fourth line on the test tray TST to the IC device storing portions on the first to third rows on the fourth line on the customer tray KST-A (leaving the fourth row on the fourth line empty) in the same arrangement, and convey IC devices 2 having test results A on the seventh and eighth rows on the first line on the test tray TST to the IC device storing portions on the third and fourth rows on the fifth line on the customer tray KST-A (leaving the first and second rows on the fifth line empty) in the same arrangement.

Although IC devices 2 having test results A still remain on the test tray TST, since conveyance to the IC device storing portions up to fifth line (the final line) has completed on the customer tray KST-A, it is no longer possible to load IC devices 2 having test results A in an arrangement of being held by the suction pads 407 onto the customer tray KST-A as explained above.

Accordingly, the IC devices 2 having test results A may be conveyed to the second customer tray KST-A, however, in this example, the IC devices 2 having test results A remaining on the test tray TST are conveyed to empty IC device storing portions on the same customer tray KST-A, on which no IC devices 2 having test results A have been loaded, so as not to leave any space in the next step. By performing this step, IC devices 2 having test results A can be loaded without leaving any space on the customer tray KST-A and it is possible to use the customer tray KST-A efficiently.

Specifically, as shown in FIG. 9(E), the four suction pads 407 hold IC devices 2 having test results A on the sixth and eighth rows on the second line and fifth and sixth rows on the third line on the test tray TST and convey them to the empty IC device storing portions on the first and second rows on the second line and third and fourth rows on the third line on the customer tray KST-A.

Subsequently, as shown in FIG. 9(F), the four suction pads 407 hold the IC devices 2 having test results A on the seventh row on the third line and fifth and eighth rows on the fourth line on the test tray TST and convey to the empty IC device storing portions on the fourth row on the fourth line and first and second rows on the fifth line.

As explained above, when all of the IC devices 2 having test results A stored on the test tray TST are conveyed to the customer tray KST-A, then, as shown in FIG. 9(G) to (H), IC devices 2 having test results B are conveyed to the customer tray KST-B for storing devices with test results B and IC devices 2 having test results C are conveyed to the customer tray KST-C for storing devices with test results C.

Namely, as shown in FIG. 9(G), the suction pads 407 on the first to third rows hold IC devices 2 having test results B on the sixth row on the first line, fifth row on the second line and third row on the third line on the test tray TST and convey them to the IC device storing portions on the first to third rows on the first line on the customer tray KST-B.

Next, as shown in FIG. 9(F), the suction pads 407 on the first and second rows hold IC devices 2 having test results C on the second row on the second line and seventh row on the fourth line on the test tray TST and convey them to the IC device storing portions on the first and second rows on the first line on the customer tray KST-C.

Note that, in this example, the number of IC devices 2 having test results B and that of IC devices 2 having test results C stored on the test tray TST are not large, so that the plurality of scattered IC devices 2 having test results B or test results C were picked up by moving the suction pads 407; however, when the number of IC devices 2 having test results B or that of IC devices 2 having test results C is large, it is preferable to convey by the similar method as conveying the IC devices 2 having test results A explained above.

According to the conveying method of post-test IC devices 2 explained above, it is possible to reduce the number of times of touchdowns to the customer tray KST to one in one conveyance by loading post-test IC devices 2 having the one test result (test result A) onto the customer tray KST in the same arrangement as that when being held by the suction pads 407. Also, in the middle steps (FIG. 9(E) to (F)), post-test IC devices 2 having the one test result (test result A) remaining on the test tray TST are efficiently conveyed in a lot to empty IC device storing portions on the customer tray KST. Accordingly, comparing with conventional conveying methods, the number of times of touchdowns as a whole can be reduced, so that the conveyance efficiency can be improved and throughput and test efficiency can be improved.

Also, in the conveying method of post-test IC devices 2 as explained above, only the IC devices 2 having test results A are held and conveyed to the customer tray KST-A, so that mixture of post-test IC devices 2 having other test results (test results B and C) on the customer tray KST-A can be prevented unfailingly.

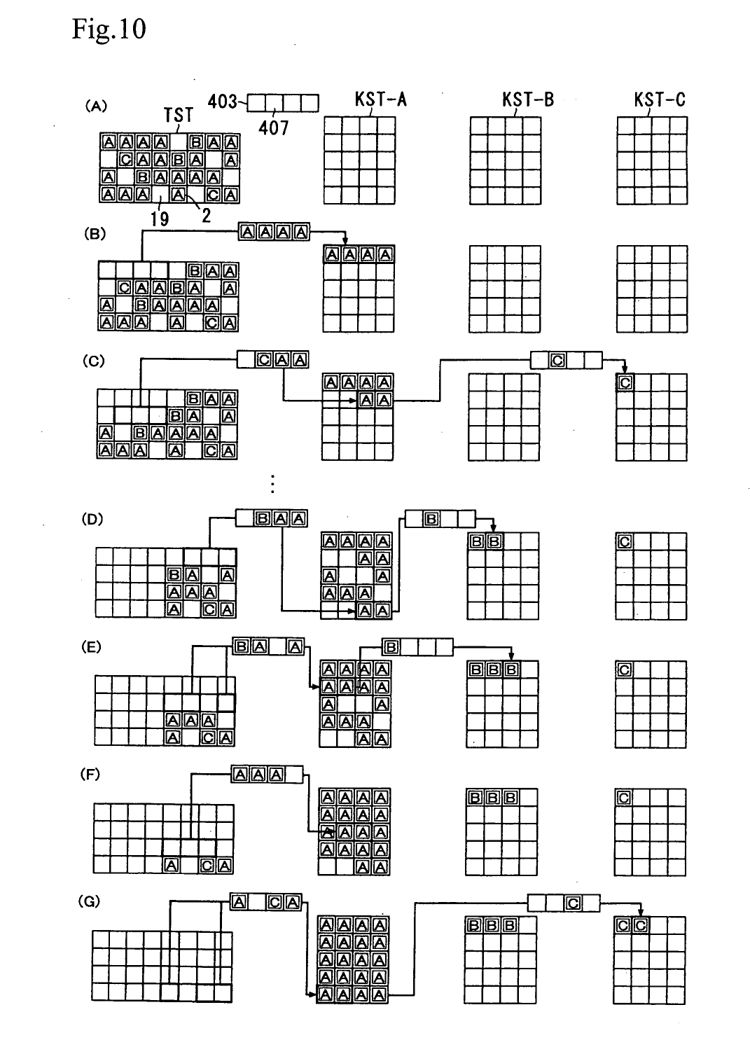

Next, with reference to FIG. 10, another example of a conveying method of post-test IC devices 2 from the test tray TST to classification customer trays KST in the above handler 1 will be explained.

As shown in FIG. 10(A), there are post-test IC devices 2 having different test results (for example, test results A, B and C) on one test tray TST. Parts where no IC device 2 exists are IC device storing portions 19 to which no pre-test IC device 2 was conveyed for the reason of being corresponding to turned-off sockets. In this example, IC devices 2 having test results A, B and C are picked up without discriminating from the test tray TST and conveyed to classification customer trays KST corresponding to respective test results.

First, on the first (the left end in FIG. 10) to fourth rows on the first line (the upper end in FIG. 10) on the test tray TST, the four suction pads 407 on the movable head 403 of the X-Y conveyor device 404 hold, as shown in FIG. 10(B), IC devices 2 on the first to fourth rows on the first line on the test tray TST at a time. The IC devices 2 are all having test results A, so that they are placed in the IC device holding portions on the first (the left end in FIG. 10) to fourth rows on the first line (the upper end in FIG. 10) on the customer tray KST-A for storing devices with test results A in the same arrangement. At this time, the number of times of touchdowns to the customer tray KST-A is one.

Next, on the first to fourth rows on the second line on the test tray TST, the suction pads 407 hold IC devices 2 on the second to fourth rows on the second line on the test tray TST at a time as shown in FIG. 10(C). The suction pad 407 on the second row holds an IC device 2 having a test result C, the suction pad 407 on the third row holds an IC device 2 having a test result A, and the suction pad 407 on the fourth row holds an IC device 2 having a test result A. Therefore, the suction pads 407 on the third and fourth rows store the IC devices 2 having test results A in the IC device storing portions on the third and fourth rows on the second line on the customer tray KST-A in the same arrangement, and the suction pad 407 on the second row stores the IC device 2 having a test result C in the IC device storing portion on the first row on the first line on the customer tray KST-C for storing devices with test results C.

In the same way as explained above, respective IC devices 2 on the first to fourth rows on the third line, first to fourth rows on the fourth line and fifth to eighth rows on the first line on the test tray TST are conveyed to the customer trays KST-A, KST-B and KST-C according to the test results (refer to FIG. 10(D)). Note that the number of IC devices 2 having test results B and those having test results C is small, so that they are loaded in the IC device storing portions successively from the first row on the first line on the customer trays KST-B and KST-C without leaving any space. However, when the number is large, it is preferable to load them in the same arrangement as that when being held by the suction pads 407 to the IC device storing portions on the customer trays KST-B and KST-C as in the same way as IC devices 2 having test results A.

At this stage, conveyance of IC devices 2 having test results A has completed up to the IC devices storing portions on the fifth line (the final line) on the customer tray KST-A, so that it is no longer possible to load IC deices 2 having test results A on the customer tray KST-A in the same arrangement as that when being held by the suction pads 407 as explained above.

Accordingly, the IC devices 2 having test results A may be conveyed to the second customer tray KST-A, however, in this example, the IC devices 2 having test results A remaining on the test tray TST are conveyed to empty IC device storing portions on the same customer tray KST-A to which no IC devices 2 having test results A have been loaded, so that no empty space is left as shown in FIG. 10(E) to (G) in the next step. By performing this step, IC devices 2 having test results A can be loaded without leaving any space on the customer tray KST-A and it is possible to use the customer tray KST-A efficiently.

IC devices 2 having test results B and those having test results C remaining on the test tray TST are, as shown in FIG. 10(E) to (G), successively loaded on IC device storing portions on the customer trays KST-B and KST-C without leaving any space.

According to the conveying method of post-test IC devices 2 explained as above, as a result that post-test IC devices 2 having test results A are loaded on the customer tray KST in the same arrangement as that when being held by the suction pads 407, the number of times of touchdowns to the customer tray KST-A is reduced to one in one conveyance. Also, in the middle steps (FIG. 10(E) to (G)), post-test IC devices 2 having test results A remaining on the test tray TST are efficiently conveyed in a lot to empty IC device storing portions on the customer tray KST. Accordingly, comparing with conventional conveying methods, the number of times of touchdowns as a whole can be reduced, so that the conveyance efficiency can be improved and throughput and test efficiency can be improved.

Furthermore, in the conveying method of post-test IC devices 2 as explained above, a plurality of post-test IC devices 2 having different test results are held and conveyed at a time by the same movable head 403, so that the number of times that the movable head 403 moves between the test tray TST and customer trays KST can be reduced, consequently, the conveyance efficiency can be improved.

Here, after repeating the conveyance of post-test IC devices 2 in the above explained method, IC devices 2 having test results A may be stored in IC device storing portions on the customer tray KST-A without leaving any space in the same way as in the IC devices 2 having test results B or test results C at a predetermined timing, preferably, by using as a trigger information on supply customer trays KST storing pre-test IC devices relating to one test lot.

Information on the supply trays to be the trigger may be, for example, information that the last or a predetermined supply customer tray KST in one test lot is set to the loader section 300 of the handler 1 or information that conveyance of pre-test IC devices 2 from the last or a predetermined supply customer tray KST to the test tray TST is completed, etc. The last or predetermined supply tray can be recognized by the number of customer trays KST stored in the handler 1 or by using a sensor, etc. provided to the IC magazine 200 and the pre-test IC stocker 201, etc.

For example, when information on the last supply customer tray KST is used as the trigger, it is detected that the test will be finished soon, therefore, in the last step, it is possible to prevent making a customer tray KST-A with empty spaces to which IC devices 2 having test results A are not conveyed. Particularly, in the case of moving on to the next customer tray KST-A in the step in FIG. 10(D) and later, it is possible to prevent customer trays KST-A from being used wastefully many. At the same way, when information on a predetermined supply customer tray KST is used as the trigger, it is possible to prevent, at a predetermined stage, generation of a customer tray KST having empty parts to which IC devices 2 with test results A are not conveyed.

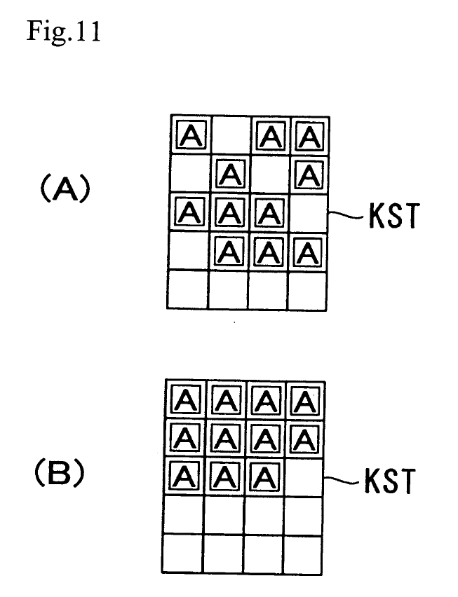

Also, at a predetermined stage after repeating the conveyance of post-test IC devices 2 in the method explained above, preferably, at the stage when all IC devices 2 having test results A among post-test IC devices 2 relating to one test lot are loaded on the customer trays KST-A; in the case where there are IC device storing portions in an empty state by not being loaded with any IC devices 2 with test results A on the customer tray KST-A as shown in FIG. 11(A), the already loaded IC devices 2 with test results A may be reloaded in the empty IC device storing portions from the first row on the first line so as not to leave any space as shown in FIG. 11(B).

By performing the above steps, it is possible to prevent generation of empty portions with no IC devices 2 having test results A held therein on the last customer tray KST-A.

The embodiments explained above are described to facilitate understanding of the present invention and are not to limit the present invention. Accordingly, respective elements disclosed in the above embodiments include all design modifications and equivalents belonging to the technical scope of the present invention.

For example, in the above embodiments, IC devices 2 are conveyed by the test tray TST, however, it is not limited to that and, for example, the IC devices 2 stored on the customer tray KST may be picked up by suction heads and directly pressed against the sockets on the test head without using a test tray TST. In that case, pre-test IC devices 2 are conveyed from the supply customer tray KST to the sockets, and post-test IC devices 2 are conveyed from the sockets to the classification customer trays KST.

### INDUSTRIAL APPLICABILITY

The electronic device conveying method and the electronic device handling apparatus of the present invention are useful for conveying electronic devices efficiently and improving the throughput and test efficiency.

1. An electronic device conveying method for conveying a plurality of pre-test electronic devices from the first area where pre-test electronic devices are loaded to the second area where pre-test electronic devices are to be loaded or tested, in an electronic device handling apparatus comprising a holder capable of holding and conveying a plurality of pre-test electronic devices at a time:
wherein the respective positions in the second area are set to be available for conveyance when pre-test electronic devices may be conveyed to or to be unavailable for conveyance when no pre-test electronic devices should be conveyed thereto in accordance with predetermined conditions;
comprising
a first step of leaving pre-test electronic devices loaded on positions in the first area corresponding to positions in the second area set to be unavailable for conveyance, holding by the holder only pre-test electronic devices loaded on positions in the first area corresponding to positions in the second area set to be available for conveyance and, without changing an arrangement of the pre-test electronic devices being held, conveying directly or indirectly from the first area to the second area set to be available for conveyance; and
a second step of conveying from the first area to the second area set to be available for conveyance the pre-test electronic devices left at the first area because they are loaded on positions in the first area corresponding to the second area set to be unavailable for conveyance.

2. The electronic device conveying method as set forth in claim 1, wherein the first step is performed repeatedly until all of pre-test electronic devices loaded on positions in the first area corresponding to positions in the second area set to be available for conveyance among pre-test electronic devices loaded at the first area are conveyed to the second area and, then, the second step is performed.

3. The electronic device conveying method as set forth in claim 1, wherein the first area is electronic device storing portions of a supply tray.

4. The electronic device conveying method as set forth in claim 1, wherein the second area is electronic device storing portions of a test tray.

5. A method of conveying a plurality of post-test electronic devices while classifying them based on test results from the first area where post-test electronic devices are loaded to the second area where post-test electronic devices are to be loaded in an electronic device handling apparatus comprising a holder capable of holding and conveying a plurality of post-test electronic devices at a time:
comprising a first step of holding by the holder post-test electronic devices having predetermined or arbitrary test results among post-test electronic devices loaded on the first area and conveying them directly or indirectly from the first area to the second area, and loading post-test electronic devices having the one test result among the post-test electronic devices having predetermined or arbitrary test results on the second area in an arrangement corresponding to an arrangement of being held by the holder.

6. The electronic device conveying method as set forth in claim 5, wherein the post-test electronic devices having predetermined or arbitrary test results only include the post-test electronic devices having the one test result.

7. The electronic device conveying method as set forth in claim 5, wherein the post-test electronic devices having predetermined or arbitrary test results include the post-test electronic devices having the one test result and post-test electronic devices having other test results.

8. The electronic device conveying method as set forth in claim 5, wherein the predetermined or arbitrary test results may include all kinds of test results, and post-test electronic devices are held regardless of the test results when holding the post-test electronic devices loaded on the first area by the holder.

9. The electronic device conveying method as set forth in claim 5, wherein the first area is electronic device storing portions on a test tray, and the second area is electronic device holding portions on a classification tray.

10. The electronic device conveying method as set forth in claim 5, furthermore comprising a second step of conveying and loading post-test electronic devices having the one test result onto the second area in an empty state on which post-test electronic devices have not been loaded in the first step.

11. The electronic device conveying method as set forth in claim 5, wherein the first step is repeatedly performed until the first step can be no longer performed and, then, the second step is performed.

12. The electronic device conveying method as set forth in claim 11, wherein:
the second area is electronic device storing portions on a classification tray; and
the first step is repeatedly performed until the first step can be no longer performed for one classification tray.

13. The electronic device conveying method as set forth in claim 11, wherein:
the second area is electronic device storing portions on a classification tray; and
the first step is repeatedly performed until the first step can be no longer performed for predetermined number of classification trays.

14. The electronic device conveying method as set forth in claim 11, wherein:
the second area is electronic device holding portions on a classification tray; and
the first step is repeatedly performed until the first step can be no longer performed under a condition of allowing the classification trays to be exchanged.

15. The electronic device conveying method as set forth in claim 5, furthermore comprising a third step of conveying post-test electronic devices having the one test result to the second area and loading on the second area without leaving any spaces between them.

16. The electronic device conveying method as set forth in claim 15, wherein the third step is performed by using information on a supply tray storing pre-test electronic devices relating to one test lot as a trigger.

17. The electronic device conveying method as set forth in claim 5, furthermore comprising a fourth step of reloading post-test electronic devices already loaded on the second area to the second area in an empty state on which post-test electronic devices have not been loaded in the first step.

18. The electronic device conveying method as set forth in claim 17, wherein the fourth step is performed after all post-test electronic devices having the one test result among post-test electronic devices relating to one test lot are loaded on the second area.

19. (canceled)
